(19) United States
(12) Patent Application Publication
(10) Pub. No.: US 2013/0232784 A1
(43) Pub. Date: Sep. 12, 2013

(54) METHOD OF MANUFACTURING WIRING SUBSTRATE

(71) Applicant: NGK SPARK PLUG CP., LTD, Nagoya-shi (JP)

(72) Inventors: Toshinori HIDA, Kani-shi (JP); Kenji SUZUKI, Iwakura-shi (JP); Shinnosuke MAEDA, Nagoya-shi (JP)

(73) Assignee: NGK SPARK PLUG CO., LTD, Nagoya-shi (JP)

(21) Appl. No.: 13/786,157

(22) Filed: Mar. 5, 2013

(30) Foreign Application Priority Data
Mar. 6, 2012 (JP) 2012-049622

(51) Int. Cl. H05K 3/00

(52) U.S. Cl. CPC H05K 3/0094
USPC 29/852

(57) ABSTRACT

A method of manufacturing a wiring substrate includes: a process of forming a first laminate structure in which one or more conductor layers and one or more resin insulating layers are laminated on a supporting substrate; a process of laminating a metal core substrate, which has a metal layer disposed on the top main surface thereof, on the first laminate structure so that a bottom main surface of the metal core substrate comes in contact with the first laminate structure, and a process of forming a second laminate structure in which one or more conductor layers and one or more resin insulating layers are laminated on the metal core substrate.

### CROSS REFERENCE TO RELATED APPLICATIONS

The present application claims priority from Japanese Patent Application No. 2012-049622, which was filed on Mar. 6, 2012, the disclosure of which is herein incorporated by reference in its entirety.

### BACKGROUND OF THE INVENTION

1. Field of the Invention

The present invention relates to a method of manufacturing a wiring substrate.

2. Description of Related Art

Generally, a wiring substrate in which a build-up layer is formed by alternately laminating resin insulating layers and conductor layers on both sides of a core substrate is used as a package which mounts electronic components (JP-A-2004-31812). The core substrate is formed of, for example, a resin including a glass fiber. Since the core substrate has a high stiffness and plays a role of reinforcing the build-up layer, generally, the core substrate is formed to be thick, which hinders the thinning of the wiring substrate.

In recent years, a wiring substrate having a thinned core substrate has been proposed. However, when the core substrate is thinned, the stiffness of an assembly including the core substrate in a manufacturing process (a substrate in the middle of a manufacturing process to become a wiring substrate) decreases. As a result, it is not possible to normally transport the core substrate or the assembly, and there is a problem in that the core substrate or the assembly comes in contact with a transporting device during transportation such that the core substrate or the assembly is damaged.

In addition, in the respective manufacturing processes, when the core substrate or the assembly is fixed and provided for a predetermined manufacturing process, there is a problem in that the core substrate or the assembly is bent, and it became difficult to accurately perform treatments (for example, a plating treatment) in the respective manufacturing processes. As a result, there is a problem in that the manufacturing yield of the wiring substrate decreases.

From the above viewpoint, a wiring substrate not having a core substrate, which is suitable for thinning, (a so-called coreless wiring substrate) is proposed (Japanese Patent No. 4,267,903). This coreless wiring substrate is obtained as a target wiring substrate in a manner that, for example, a build-up layer is formed on a supporting substrate having a detaching sheet, which is formed by laminating two detachable metal films, provided on the surface, and then the build-up layer is separated from the supporting body by separating the detaching sheet from the detachment interface.

However, since the above coreless wiring substrate does not have a core substrate inside, there are problems in that the stiffness is low, the attention needs to be paid when handling the wiring substrate, and the usage is limited.

### BRIEF SUMMARY OF THE INVENTION

An object of the invention is to provide a method of manufacturing a wiring substrate which has a laminate structure in which at least one conductor layer and at least one resin insulating layer are alternately laminated on both surfaces of a core substrate, and can be thinned without decreasing the manufacturing yield.

In order to achieve the above object, in accordance with one aspect of the invention, a method of manufacturing a wiring substrate includes a process of forming a first laminate structure in which one or more conductor layers and one or more resin insulating layers are laminated on a supporting substrate, a process of forming (i.e., laminating) a metal core substrate, which has a metal layer disposed on a top main surface thereof, on the first laminate structure so that the bottom main surface of the metal core substrate comes in contact with the first laminate structure, and a process of forming a second laminate structure in which one or more conductor layers and one or more resin insulating layers are laminated on the metal core substrate.

Accordingly, in a method of manufacturing a so-called coreless wiring substrate in which a laminate structure having at least one conductor layer and at least one resin insulating layer laminated on a supporting substrate is formed, a metal core substrate is also laminated along with the laminate structure, and, furthermore, an additional laminate structure having the same configuration is laminated on the metal core substrate.

In the method of manufacturing a coreless wiring substrate, since the supporting substrate is removed after forming the laminate structure on the supporting substrate in the above manner, ultimately, a configuration, in which the metal core substrate is sandwiched by the laminate structures made of at least one conductor layer and at least one resin insulating layer, that is, a wiring substrate having the metal core substrate, remains.

Furthermore, since the method of manufacturing a coreless wiring substrate is used as described above, the laminate structure or the metal core substrate is formed on the supporting substrate in the manufacturing process. Therefore, even in a case in which the thickness of the metal core substrate is decreased, a decrease in the stiffness of an assembly in a manufacturing process can be suppressed by sufficiently thickening the supporting substrate. Therefore, it is possible to horizontally transport the assembly in a manufacturing process, and it can be prevented that the assembly comes in contact with a transporting device during transportation such that the metal core substrate or the assembly is damaged.

In addition, in the respective manufacturing processes, when the assembly is fixed and provided for a predetermined manufacturing process, it can be prevented that the assembly is bent such that it becomes difficult to accurately perform a predetermined treatment (for example, plating). Therefore, it is possible to improve the yield when manufacturing the wiring substrate.

In an example of the invention, the metal core substrate can be formed by laminating, in the following order, a first insulating resin layer, a metal plate in which a plurality of through holes are formed (metal plate through holes), a second insulating resin layer, and the metal layer. In this case, since the metal plate is laminated in the metal core substrate, the stiffness of the wiring substrate improves, and the wiring substrate bends less. Therefore, it is possible to thin the wiring substrate without decreasing the manufacturing yield of the wiring substrate. Furthermore, in specific examples the first and/or second insulating resin layers can be prepreg layers.

Furthermore, in an example of the invention, the process of forming (i.e., laminating) the metal core substrate can further comprise forming through holes in the metal core substrate at locations of the plurality of through holes (metal plate through holes), and filling the through holes through plating. In this case, since a plating metal, which fills the through holes, functions as an interlayer connector (via) which electrically connects the laminate structures formed on both surfaces of the metal core substrate, it is possible to shorten the length of a wire for electrically connecting the laminate structures and to prevent deterioration of the transmission performance of high-frequency signals and the like.

In addition, in an example of the invention, in the process of laminating the metal core substrate, it is possible that after the metal core substrate is laminated on the first laminate structure, through holes are formed in the metal core substrate at locations of the plurality of through holes (metal plate through holes), and after plate layers are formed on the inner walls of the through holes formed in the metal core substrate, a resin insulating layer is formed using a resin insulating material that at least fills the through holes formed in the metal core substrate. In this case, it is possible to remove cumbersome processes, such as a through hole plating with respect to the metal core substrate, a filling of the through holes through resin filling, and a grinding process of the filling resin, which are performed in a metal core substrate-including wiring substrate of the related art. That is, it is possible to simplify the process of manufacturing the metal core substrate-including wiring substrate.

In addition, in an example of the invention, the through holes can be formed in the metal core substrate by radiation of laser light. In this case, and when the metal layer is not present at the places at which the through holes are to be formed (i.e., at locations of opening portions), for example, in a case in which the through holes are formed by the radiation of laser light, it is possible to decrease the radiation energy and to decrease the manufacturing costs of the metal core substrate-including wiring substrate.

As described above, according to the invention, it is possible to provide a method of manufacturing a wiring substrate which has a laminate structure in which at least one conductor layer and at least one resin insulating layer are alternately laminated on both surfaces of a metal core substrate, and can be thinned without decreasing the manufacturing yield.

### BRIEF DESCRIPTION OF THE DRAWINGS

FIG. 1 is a plan view of a wiring substrate of a first embodiment.

FIG. 2 is a plan view of the wiring substrate of the first embodiment.

FIG. 3 is a view showing a cross-sectional view of the wiring substrate shown in FIGS. 1 and 2 is cut along a line I-I.

FIG. 4 is a process chart of a method of manufacturing the wiring substrate of the first embodiment.

FIG. 5 is a process chart of the method of manufacturing the wiring substrate of the first embodiment.

FIG. 6 is a process chart of the method of manufacturing the wiring substrate of the first embodiment.

FIG. 7 is a process chart of the method of manufacturing the wiring substrate of the first embodiment.

FIG. 8 is a process chart of the method of manufacturing the wiring substrate of the first embodiment.

FIG. 9 is a process chart of the method of manufacturing the wiring substrate of the first embodiment.

FIG. 10 is a process chart of the method of manufacturing the wiring substrate of the first embodiment.

FIG. 11 is a process chart of the method of manufacturing the wiring substrate of the first embodiment.

FIG. 12 is a process chart of the method of manufacturing the wiring substrate of the first embodiment.

FIG. 13 is a process chart of the method of manufacturing the wiring substrate of the first embodiment.

FIG. 14 is a process chart of the method of manufacturing the wiring substrate of the first embodiment.

FIG. 15 is a process chart of the method of manufacturing the wiring substrate of the first embodiment.

FIG. 16 is a process chart of the method of manufacturing the wiring substrate of the first embodiment.

FIG. 17 is a process chart of the method of manufacturing the wiring substrate of the first embodiment.

FIG. 18 is a view showing an enlarged part of a cross-section of a wiring substrate of a second embodiment.

FIG. 19 is a process chart of a method of manufacturing the wiring substrate of the second embodiment.

FIG. 20 is a process chart of the method of manufacturing the wiring substrate of the second embodiment.

FIG. 21 is a process chart of the method of manufacturing the wiring substrate of the second embodiment.

FIG. 22 is a process chart of the method of manufacturing the wiring substrate of the second embodiment.

### DETAILED DESCRIPTION OF EXEMPLARY EMBODIMENTS OF THE INVENTION

Preferred embodiments of the invention will be described with reference to the accompanying drawings.

### First Embodiment

### Wiring Substrate

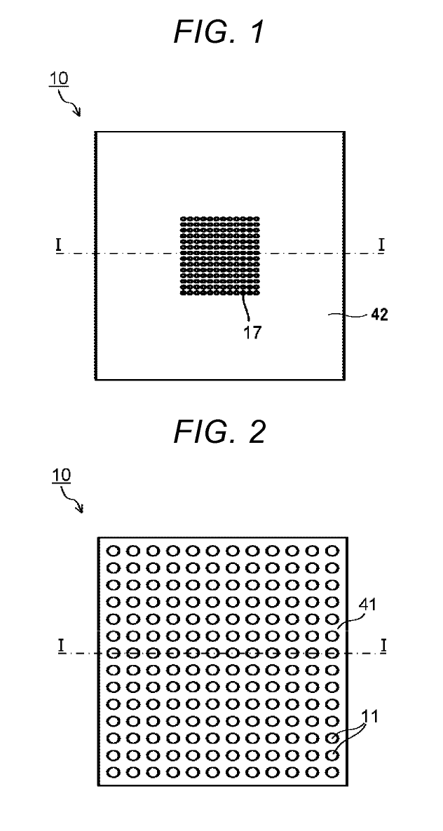

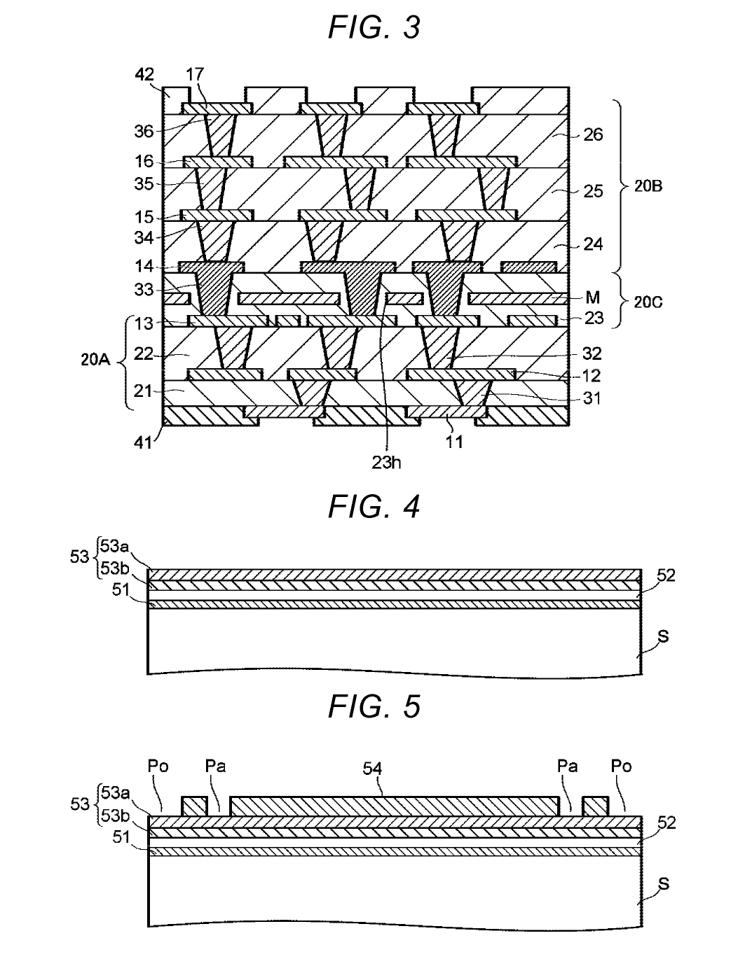

First, an example of a wiring substrate manufactured using the method of the invention will be described. FIGS. 1 and 2 are plan views of a wiring substrate of the present embodiment. FIG. 1 shows the wiring substrate 10 as seen from above, and FIG. 2 shows the wiring substrate 10 as seen from below. In addition, FIG. 3 is a view showing an enlarged cross-sectional view of the wiring substrate shown in FIGS. 1 and 2 cut along a line I-I.

Meanwhile, the wiring substrate described below is an example for clarifying the characteristics of the invention, and the wiring substrate is not particularly limited as long as the wiring substrate has a configuration in which a metal core substrate is sandwiched by a first laminate structure and a second laminate structure which include at least one conductor layer and at least one resin insulating layer alternately laminated therein.

The wiring substrate 10 shown in FIGS. 1 through 3 has a first laminate structure 20A, a second laminate structure 20B, and a metal core substrate 20C sandwiched by the first laminate structure 20A and the second laminate structure 20B.

The first laminate structure 20A has a first conductor layer 11 to a third conductor layer 13, a first resin insulating layer 21, a second resin insulating layer 22, a first via conductor 31, and a second via conductor 32, and has a configuration in which the first conductor layer 11, the first resin insulating layer 21, the second conductor layer 12, the second resin insulating layer 22, and the third conductor layer 13 are laminated in this order. In addition, the first via conductor 31 electrically connects the first conductor layer 11 and the second conductor layer 12, and the second via conductor 32 electrically connects the second conductor layer 12 and the third conductor layer 13.

The second laminate structure 20B has a fourth conductor layer 14 to a seventh conductor layer 17, a fourth resin insulating layer 24 to a sixth resin insulating layer 26, a fourth via conductor 34 to a sixth via conductor 36, and has a configuration in which the fourth conductor layer 14, the fourth resin insulating layer 24, the fifth conductor layer 15, the fifth resin insulating layer 25, the sixth conductor layer 16, the sixth resin insulating layer 26, and the seventh conductor layer 17 are laminated in this order. In addition, the fourth via conductor 34 electrically connects the fourth conductor layer 14 and the fifth conductor layer 15, the fifth via conductor 35 electrically connects the fifth conductor layer 15 and the sixth conductor layer 16, and the sixth via conductor 36 electrically connects the sixth conductor layer 16 and the seventh conductor layer 17.

Meanwhile, the first conductor layer 11 to the seventh conductor layer 17 are made of a conductor having a low electric resistance, such as copper. In addition, the first resin insulating layer 21, the second resin insulating layer 22, and the fourth resin insulating layer 24 to the sixth resin insulating layer 26 are made of a thermosetting resin composition. The thermosetting resin composition may include a silica filler and the like as necessary.

The metal core substrate 20C has a third resin insulating layer 23, a metal plate M disposed in the third resin insulating layer 23, and a third via conductor 33. The third resin insulating layer 23 is formed by thermally curing two insulating resin substrates, such as heat-resistant resin plates (for example, bismaleimide-triazine resin plates), fiber-reinforced resin plates (for example, a glass fiber-reinforced epoxy resin), or the like. The metal plate M is made of a metal having a low coefficient of thermal expansion such as invar (an alloy of nickel and iron) or a good conductor, such as copper, and through holes 23h (metal plate through holes) are formed in advance at locations at which the third via conductor 33 is formed. The thickness of the metal core substrate 20C can be set to, for example, 100 μm to 200 μm.

Meanwhile, a first resist layer 41 is formed on the first conductor layer 11 so as to partially expose the first conductor layer 11, and a second resist layer 42 is formed on the seventh conductor layer 17 so as to partially expose the seventh conductor layer 17.

The portions of the first conductor layer 11 exposed from the first resist layer 41 function as rear surface lands (LGA pads) for connecting the wiring substrate 10 to a major board, and are arrayed in a rectangular shape on the rear (bottom) surface of the wiring substrate 10. The portions of the seventh conductor layer 17 exposed from the second resist layer 42 function as pads (FC pads) for flip chip connection of a semiconductor element or the like (not shown) with respect to the wiring substrate 10, configure semiconductor element-mounting areas, and are arrayed in a rectangular shape at the substantially center portion on the surface (top) of the wiring substrate 10.

In addition, while reference symbols are not given, portions of the first conductor layer 11 to the seventh conductor layer 17 which are connected with the first via conductor 31 to the sixth via conductor 36 configure via lands (via pads), and portions of the first conductor layer 11 to the seventh conductor layer 17 which are not connected with the first via conductor 31 to the sixth via conductor 36 configure wiring layers. The size of the wiring substrate 10 can be set to, for example, 400 mm×400 mm×0.4 mm.

Method of Manufacturing Wiring Substrate

Next, a method of manufacturing the wiring substrate 10 shown in FIGS. 1 through 3 will be described.

FIGS. 4 through 17 are process charts of the method of manufacturing the wiring substrate 10 of the embodiment. Meanwhile, the process charts shown in FIGS. 4 through 17 correspond to the cross-sectionalal views of the wiring substrate 10 shown in FIG. 3.

In addition, in the embodied manufacturing method of the invention, substantially, the wiring substrates 10 are formed on both sides of a supporting substrate; however, in the embodiment, in order to clarify the characteristics of the manufacturing method of the invention, a case in which the wiring substrate 10 is formed only on one side of the supporting substrate will be described.

First, as shown in FIG. 4, a supporting substrate S having copper foils 51 attached to both surfaces is prepared. The supporting substrate S can be formed of, for example, a heat-resistant resin plate (for example, a bismaleimide-triazine resin plate), a fiber-reinforced resin plate (for example, a glass fiber-reinforced epoxy resin plate), or the like. In addition, as described in detail below, in order to suppress bending of an assembly in a manufacturing process, the thickness of the supporting substrate S can be set to, for example, 0.4 mm to 1.0 mm. Next, detaching sheets 53 are pressed and molded on the copper foils 51 formed on the both surfaces of the supporting substrate S using, for example, thermal vacuum pressing through prepreg layers 52 as adhesive layers.

The detaching sheet 53 is formed of, for example, a first metal film 53a and a second metal film 53b, and both films are configured to be joined through Cr plating or the like and to be mutually detachable using an external tensile force. Meanwhile, the first metal film 53a and the second metal film 53b can be formed of a copper foil.

Next, as shown in FIG. 5, photosensitive dry films are laminated on the detaching sheets 53 formed on both sides of the supporting substrate S respectively, and mask patterns 54 are formed using exposure and development. In the mask pattern 54, openings that correspond to alignment mark-forming portions Pa and outer circumferential portion-demarcating portions Po are formed respectively.

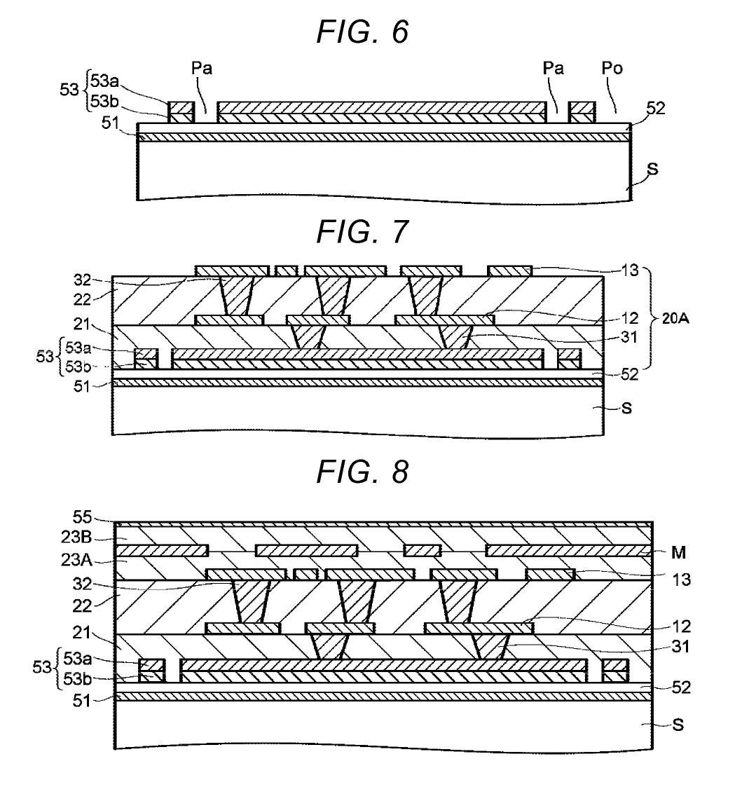

Next, as shown in FIG. 6, on the supporting substrate S, an etching treatment is performed on the detaching sheet 53 through the mask pattern 54, and the alignment mark-forming portions Pa and the outer circumferential portion-demarcating portions Po are formed in the detaching sheet 53 at locations which correspond to the openings. Meanwhile, after the alignment mark-forming portions Pa and the outer circumferential portion-demarcating portions Po are formed, the mask pattern 54 is etched and removed.

In addition, it is preferable that, after the mask pattern 54 is removed, an etching treatment be performed on the exposed surface of the detaching sheet 53 so as to coarsen the surface. Thereby, the adhesiveness between the detaching sheet 53 and a resin insulating layer described below can be increased.

Next, as shown in FIG. 7, a resin film is laminated on the detaching sheet 53, and is cured through pressurization and heating in a vacuum, thereby forming the first resin insulating layer 21. Thereby, the surface of the detaching sheet 53 is covered with the first resin insulating layer 21, and the opening portions that configure the alignment mark-forming portions Pa and cutouts which configure the outer circumferential portion-demarcating portions Po become filled with the first resin insulating layer 21. Thereby, an alignment mark is formed in the portions of the alignment mark-forming portions Pa.

In addition, since the outer circumferential portion-demarcating portions Po are also covered with the first resin insulating layer 21, in a detaching process using the detaching sheet 53 shown below, it is possible to prevent disadvantages that the end surface of the detaching sheet 53 is, for example, peeled off and uplifted from the prepreg layer such that the detaching process cannot be favorably performed and a target wiring substrate 10 cannot be manufactured.

Next, via holes are formed in the first resin insulating layer 21 by radiating laser light at a predetermined intensity using, for example, CO₂ gas laser or YAG laser, a desmear treatment and outline etching are performed appropriately on the via holes, and then a coarsening treatment is performed on the first resin insulating layer 21 including the via holes.

In a case in which the first resin insulating layer 21 includes a filler, since the filler is liberated and remains on the first resin insulating layer 21 when the coarsening treatment is performed, the first resin insulating layer is appropriately washed using water.

In addition, after the water washing, it is possible to perform air blowing. Thereby, even in a case in which the liberated filler is not completely removed through the water washing, it is possible to complement the removal of the filler through the air blowing.

After that, pattern plating is performed on the first resin insulating layer 21 so as to form the second conductor layer 12 and the first via conductor 31. The second conductor layer 12 and the via conductor 31 are formed in the following manner using a semi-additive method. First, a non-electrolytic plating film is formed on the first resin insulating layer 21, then a resist is formed on the non-electrolytic plating film, and copper electrolytic plating is performed on portions at which the resist is not formed, thereby forming the second conductor layer and the via conductor. After the second conductor layer 12 and the first via conductor 31 are formed, the resist is peeled and removed using KOH or the like, and the non-electrolytic plating film exposed due to the removal of the resist is removed through etching.

Next, after a coarsening treatment is performed on the second conductor layer 12, a resin film is laminated on the first resin insulating layer 21 so as to cover the second conductor layer 12, and is cured through pressurization and heating in a vacuum, thereby forming the second resin insulating layer 22. After that, via holes are formed in the second resin insulating layer 22 in the same manner as in the case of the first resin insulating layer 21, and, subsequently, pattern plating is performed, thereby forming the third conductor layer 13 and the second via conductor 32. Meanwhile, detailed conditions when forming the third conductor layer 13 and the second via conductor 32 are the same as in a case in which the second conductor layer 12 and the first via conductor 31 are formed.

Therefore, it is possible to obtain the first laminate structure 20A having the first metal film 53a (which becomes the first conductor layer 11 afterward), the second conductor layer 12, the third conductor layer 13, the first resin insulating layer 21, the second resin insulating layer 22, and the first via conductor 31, and the second via conductor 32 by undergoing the processes shown in FIGS. 4 to 7.

Next, as shown in FIG. 8, a first prepreg layer 23A and a second prepreg layer 23B (first and second insulating resin layers), which become the third resin insulating layer 23 through thermal curing, are laminated on the second resin insulating layer 22 with the metal plate M sandwiched therebetween so as to cover the third conductor layer 13. In addition, a metal layer 55 is disposed on the top main surface of the prepreg 23B laminated on the metal plate M. The thickness of the metal layer 55 can be set to 1 μm to 35 μm. In addition, the metal layer 55 can be configured of the same metallic material as for the first conductor layer 11 to the seventh conductor layer 17, for example, a good electric conductor such as copper.

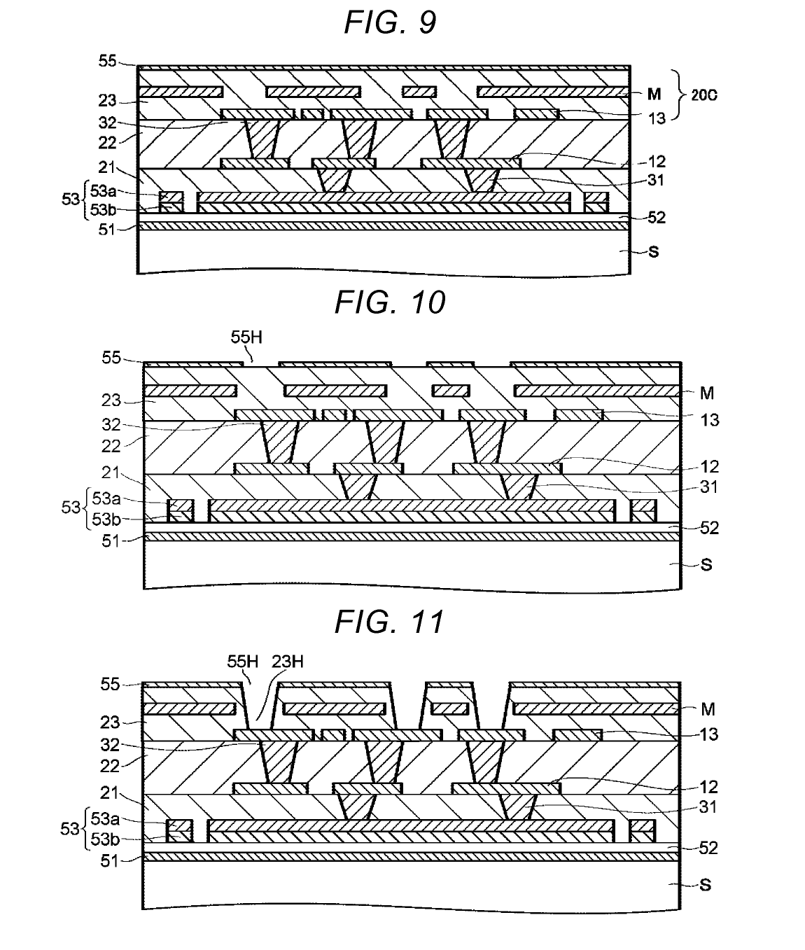

Next, as shown in FIG. 9, the prepregs 23A and 23B are thermally cured by performing thermal vacuum pressing, and the metal core substrate 20C having the metal plate M disposed in the third resin insulating layer 23 is obtained.

Meanwhile, if the thermal vacuum pressing is performed at a temperature that is the glass transition temperature or higher of the first resin insulating layer 21 and the second resin insulating layer 22 which configure the first laminate structure 20A, when the metal core substrate 20C comprising the metal layer 55, the third resin insulating layer 23 and the metal plate M is formed on the first laminate structure 20A, it is possible to improve the warpage of the first laminate structure 20A, and to improve the warpage of portions located further below than at least the metal core substrate 20C in the ultimately-obtained wiring substrate 10. Therefore, it is possible to relieve the warpage of the entire wiring substrate 10.

Next, as shown in FIG. 10, the metal layer 55 is partially etched and removed so as to form opening portions 55H, then, as shown in FIG. 11, laser light is radiated to the third resin insulating layer 23 through the opening portions 55H, and through holes 23H are formed so that the third conductor layer 13 is exposed. In this case, the through holes 23h are formed in advance in the metal plate M at places at which the through holes 23H are to be formed in the third resin insulating layer 23 in metal core substrate 20C. In the process shown in FIG. 10, since the opening portions 55H are formed in advance at places in the metal layer 55 at which the through holes 23H are to be formed in the third resin insulating layer 23, the laser light is directly radiated to the third resin insulating layer 23 without passing the metal layer 55 and the metal plate M.

Therefore, when the through holes 23H are formed in the third resin insulating layer 23 in the metal core substrate 20C using laser light, since it is possible to remove the process of forming the through holes in the metal plate M and the openings in the metal layer 55 using laser light, it is possible to decrease the radiation energy of laser light necessary when forming the through holes 23H, and to decrease the manufacturing costs of the wiring substrate 10.

However, it is also possible to remove the process shown in FIG. 10. However, in this case, since it is necessary to form the through holes in the metal plate M and the opening portions 55H in the metal layer 55 using laser light at the same time as the formation of the through holes 23H in the third resin insulating layer 23, the radiation energy of laser light necessary for formation of the through holes 23H increases. Therefore, the manufacturing costs of the wiring substrate 10 increases.

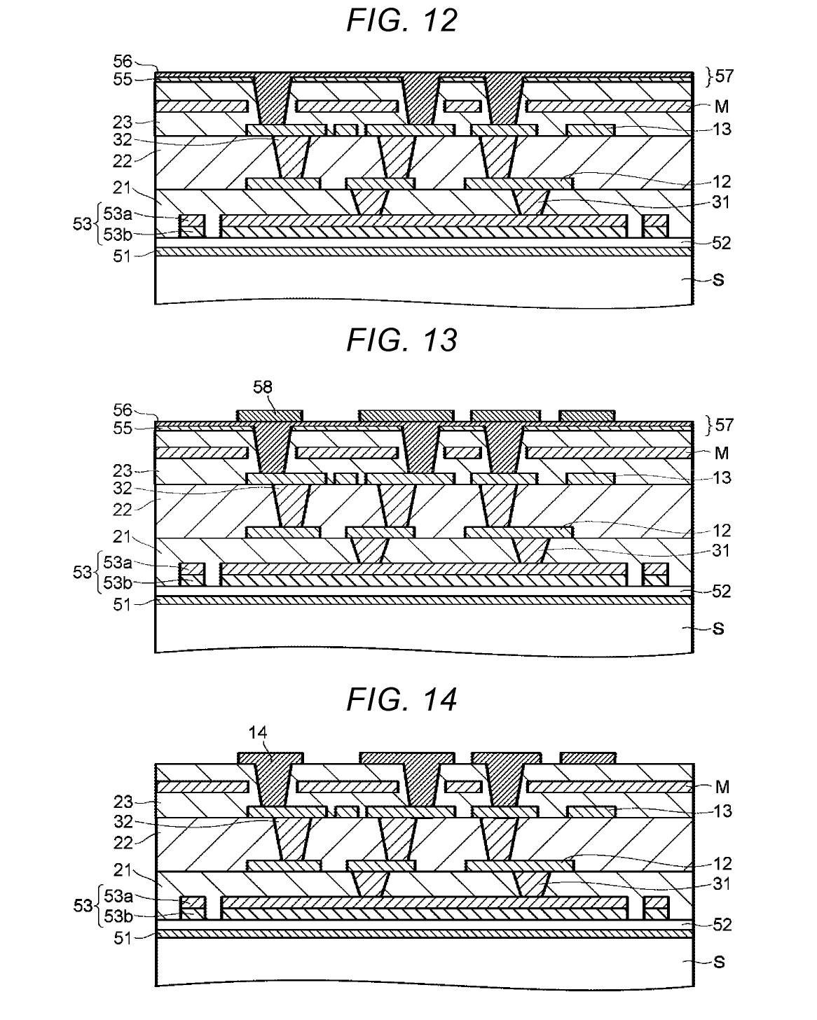

Next, on the through holes 23H, a desmear treatment and outline etching are appropriately performed, and then non-electrolytic plating is performed so as to form plating foundation layers (not shown) on the inner wall surfaces of the through holes 23H, and then a so-called field via plating treatment is performed as shown in FIG. 12, thereby filling the through holes 23H through plating. In this case, the plating metal functions as the third via conductor 33 which electrically connects the first laminate structure 20A formed on the bottom surface side of the third resin insulating layer 23 and the second laminate structure 20B formed on the top surface side of the third resin insulating layer 23, and it is possible to shorten the length of a wire for electrically connecting the laminate structures and to prevent deterioration of the transmission performance of high-frequency signals and the like.

Meanwhile, in the method of manufacturing a wiring substrate having a core substrate of the related art, it is necessary to provide through hole conductors in the core substrate in order to electrically connect laminate structures formed on both surfaces of the core substrate. Therefore, the length of a wire for electrically connecting the laminate structures is essentially increased, and there is a concern that deterioration of the transmission performance of high-frequency signals may be caused.

Meanwhile, when the field via plating treatment is performed, a plating layer 56 is formed on the metal layer 55, and the plating layer 56 laminated on the metal layer 55 collectively correspond to a metal laminate 57. As described above, the metal layer 55 can be formed of copper, the plating layer 56 can be also be formed of copper, the plating layer 56 plays the same role as the metal layer 55, and it is possible to form the metal laminate 57 to be a single metal layer.

Next, a resist pattern 58 is formed on the metal laminate (metal layer) 57 as shown in FIG. 13, and, subsequently, the metal laminate (metal layer) 57 is etched through the resist pattern 58 as shown in FIG. 14, and then, the resist pattern 58 is removed, thereby forming the fourth conductor layer 14 on the third resin insulating layer 23.

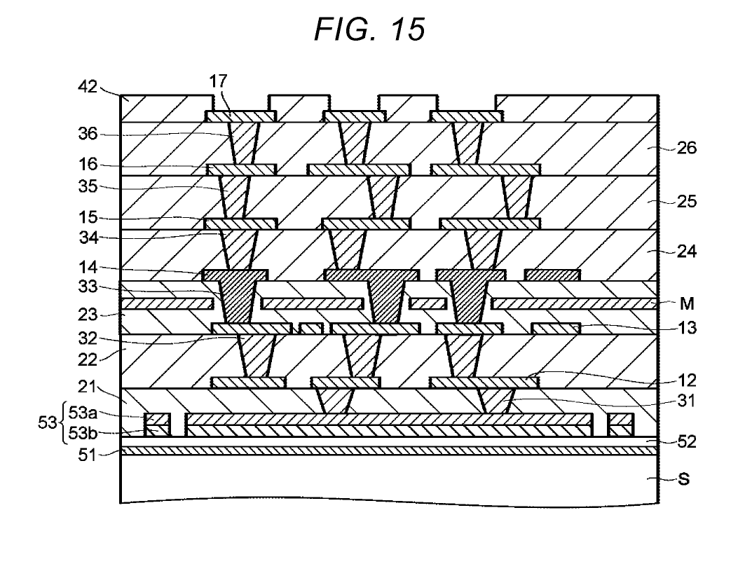

Next, a coarsening treatment is performed on the fourth conductor layer 14, then, a resin film is laminated on the third resin insulating layer 23 so as to cover the fourth conductor layer 14 as shown in FIG. 15, and is cured through pressurization and heating in a vacuum, thereby forming the fourth resin insulating layer 24. After that, via holes are formed in the fourth resin insulating layer 24 in the same manner as in the case of the first resin insulating layer 21, subsequently, the fifth conductor layer 15 and the fourth via conductor 34 are formed by performing pattern plating. Meanwhile, detailed conditions when forming the fifth conductor layer 15 and the fourth via conductor 34 are the same as in a case in which the second conductor layer 12 and the first via conductor 31 are formed.

In addition, the fifth resin insulating layer 25 and the sixth resin insulating layer 26 are sequentially formed in the same manner as in the fourth resin insulating layer 24 as shown in FIG. 15, and, furthermore, the sixth conductor layer 16 and the fifth via conductor 35, and the seventh conductor layer 17 and the sixth via conductor 36 are formed respectively in the fifth resin insulating layer 25 and the sixth resin insulating layer 26 in the same manner as in the fifth conductor layer 15 and the fourth via conductor 34. After that, the second resist layer 42 is formed so as to partially expose the seventh conductor layer 17.

The second laminate structure 20B configured of the fourth conductor layer 14 to the seventh conductor layer 17, the fourth resin insulating layer 24 to the sixth resin insulating layer 26, and the fourth via conductor 34 to the fifth via conductor 35 is obtained in the above manner.

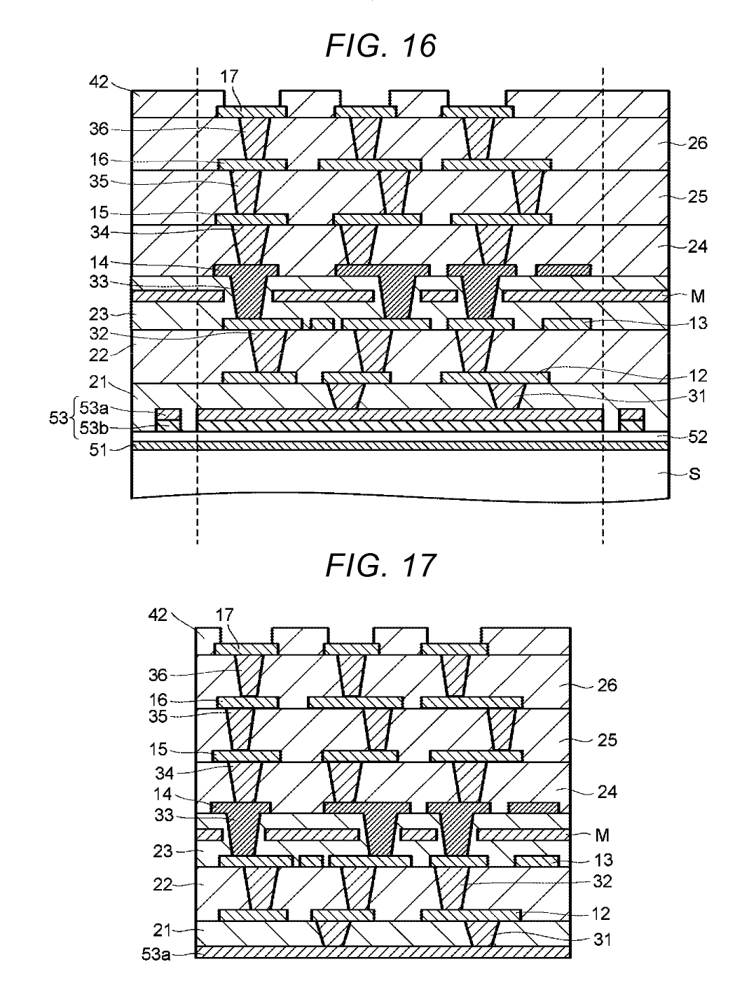

Next, the laminate including the first laminate structure 20A, the third resin insulating layer 23, and the second laminate structure 20B, which is obtained by undergoing the above processes, is cut along cutting lines set slightly inside the outer circumferential portion-demarcating portions Po as shown in FIG. 16, and the unnecessary outer circumference portions are removed.

Next, the multilayer wiring laminate obtained by undergoing the process shown in FIG. 16 is detached at the detaching interface between the first metal film 53a and the second metal film 53b which configure the detaching sheet 53 as shown in FIG. 17, and the supporting substrate S is removed from the multilayer wiring laminate.

Next, the first metal film 53a of the detaching sheet 53 remaining below the multilayer wiring laminate obtained in FIG. 17 is etched, and the first conductor layer 11 is formed. After that, the first resist layer 41 is formed so as to partially expose the first conductor layer 11, thereby obtaining the wiring substrate 10 as shown in FIG. 3.

In the embodiment, in the method of manufacturing a so-called coreless wiring substrate, in which a laminate structure is formed by laminating at least one conductor layer and at least one resin insulating layer on a supporting substrate, the metal core substrate 20C is also laminated along with the first laminate structure 20A, and, furthermore, the second laminate structure 20B having the same configuration is laminated on the metal core substrate 20C. In the method of manufacturing the coreless wiring substrate, since the supporting substrate is removed after forming the laminate structure on the supporting substrate in the above manner, ultimately, a configuration in which the metal core substrate is sandwiched by the laminate structures made of at least one conductor layer and at least one resin insulating layer, that is, a wiring substrate having the metal core substrate remains.

In the embodiment, since the method of manufacturing the coreless wiring substrate is used when manufacturing the wiring substrate 10 having the metal core substrate 20C, in the manufacturing processes, the wiring substrate 10 configured of the first laminate structure 20A, the second laminate structure 20B and the metal core substrate 20C is formed on the supporting substrate S. Therefore, even in a case in which the thickness of the metal core substrate 20C is thinned, the thickness of the supporting substrate S is sufficiently thickened so that a decrease in the stiffness of an assembly in a manufacturing process can be prevented.

Therefore, an assembly in a manufacturing process can be horizontally transported, and it is possible to avoid the fact that the assembly comes in contact with a transporting device during transportation such that the metal core substrate or the assembly is damaged. In addition, when the assembly is fixed and provided for a predetermined manufacturing process, it is possible to avoid the fact that the assembly is bent, and it becomes difficult to accurately perform, for example, a plating treatment in the respective manufacturing processes. Therefore, it is possible to obtain the wiring substrate 10 having a thin metal core substrate at a high yield.

In addition, the metal core substrate 20C in the wiring substrate 10 has the metal plate M having an excellent stiffness. Therefore, even after the wiring substrate 10 is peeled off from the supporting substrate S, an assembly in a manufacturing process can be horizontally transported, and it is possible to avoid the fact that the assembly comes in contact with a transporting device during transportation such that the metal core substrate or the assembly is damaged. In addition, when the assembly is fixed and provided for a predetermined manufacturing process, it is possible to avoid the fact that the assembly is bent, and it becomes difficult to accurately perform, for example, a plating treatment, soldering printing, and the like in the respective manufacturing processes. Therefore, it is possible to obtain the wiring substrate 10 having a thin metal core substrate at a high yield.

The method of the embodiment is not limited to manufacturing of a core substrate-including wiring substrate which has a thin metal core substrate, having a structure in which the core substrate or an assembly in a manufacturing process would bend in an ordinary manufacturing method so as to decrease the manufacturing yield, that can be applied to a case in which the core substrate is thick, and that can be manufactured using an ordinary manufacturing method at a high yield.

Meanwhile, in the embodiment, a so-called subtractive method is used when forming the fourth conductor layer 14, but it is also possible to form the fourth conductor layer using a semi-additive method instead of the subtractive method.

### Second Embodiment

### Wiring Substrate

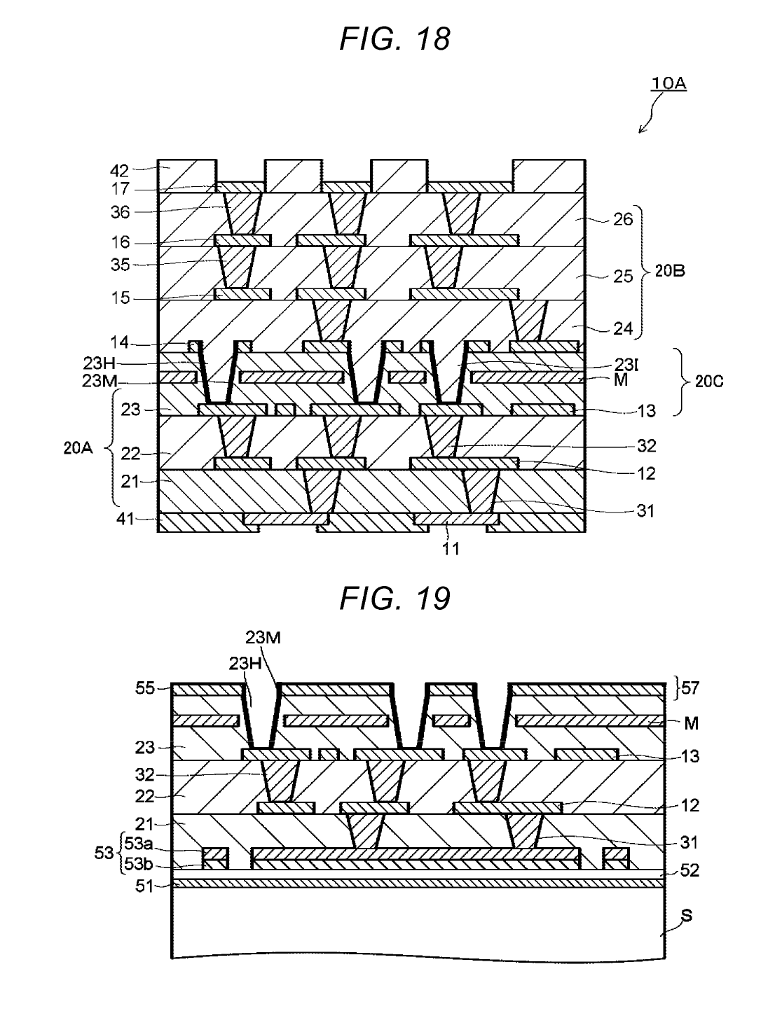

FIG. 18 is a view showing an enlarged part of a cross-section of a wiring substrate of a second embodiment, and corresponds to FIG. 3 of the first embodiment. In the drawings of the second embodiment, the same reference symbols will be used for components similar or identical to the components of the wiring substrate 10 of the first embodiment.

A wiring substrate 10A shown in FIG. 18 is different from the wiring substrate 10 shown in the first embodiment in that a plating layer 23M is formed on the wall surfaces of the through holes 23H formed in the third resin insulating layer 23, which forms the metal core substrate 20C. The plating layer 23M connects with the fourth conductor layer 14 formed on the third resin insulating layer 23, the through holes 23H are filled with a resin insulating layer 23I. The second embodiment employs the same configuration as the first embodiment in other portions.

Method of Manufacturing the Wiring Substrate

FIGS. 19 through 22 are process charts of a method of manufacturing the wiring substrate 10A of the second embodiment. Meanwhile, the process charts shown in FIGS. 19 through 22 correspond to cross-sectional views of the wiring substrate 10A shown in FIG. 18.

In addition, in the embodied manufacturing method of the invention, substantially, the wiring substrates 10A are formed on both sides of a supporting substrate; however, in the embodiment, in order to clarify the characteristics of the manufacturing method of the invention, a case in which the wiring substrate 10A is formed on only one side of the supporting substrate will be described.

First, the first laminate structure 20A and the metal core substrate 20C are formed according to the processes shown in FIGS. 4 to 9 of the first embodiment. As shown in FIG. 10, after the metal layer 55 is partially etched and removed so as to form the opening portions 55H, laser light is radiated to the third resin insulating layer 23 through the opening portions 55H as shown in FIG. 11, and the through holes 23H are formed so as to expose the third conductor layer 13.

Next, on the through holes 23H, a desmear treatment and outline etching are performed as shown in FIG. 19, then, a so-called through hole plating treatment is performed, thereby forming the plating layer 23M so as to connect the metal layer 55 to the inner wall surfaces of the through holes 23H.

Meanwhile, the plating layer 23M is formed on the metal layer 55 by performing the through hole plating treatment. As described above, since the metal layer 55 is formed of copper, and the plating layer 23M can be also formed of copper, the plating layer 23M plays the same role as the metal layer 55, and it is possible to form the metal layer 55 and the plating layer 23M to be a single metal layer.

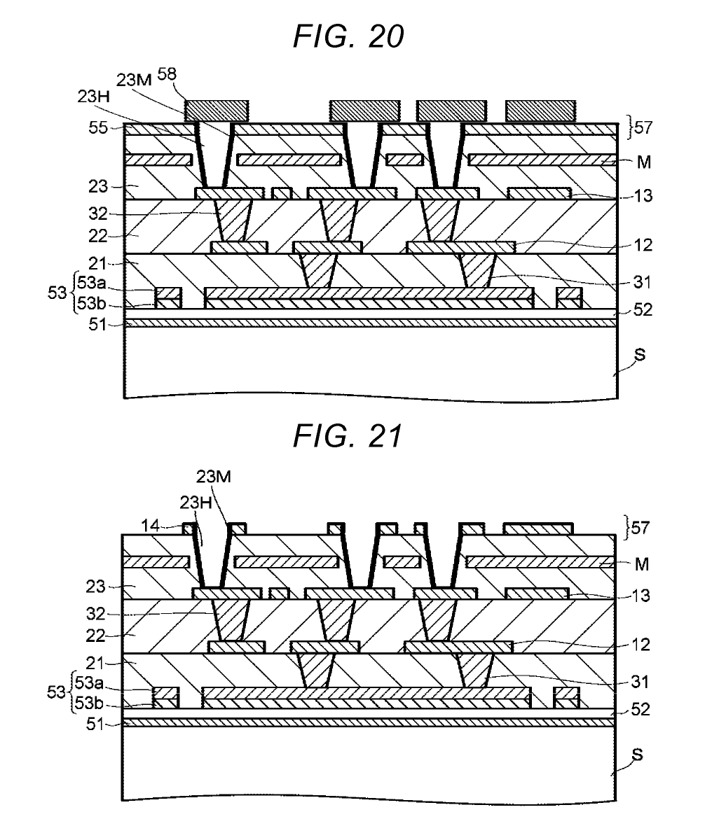

Next, the resist pattern 58 is formed on the metal layer 55 so as to block the through holes 23H as shown in FIG. 20, then, the metal layer 55 is etched through the resist pattern 58 as shown in FIG. 21, and then, the resist pattern 58 is removed, thereby forming the fourth conductor layer 14 on the third resin insulating layer 23.

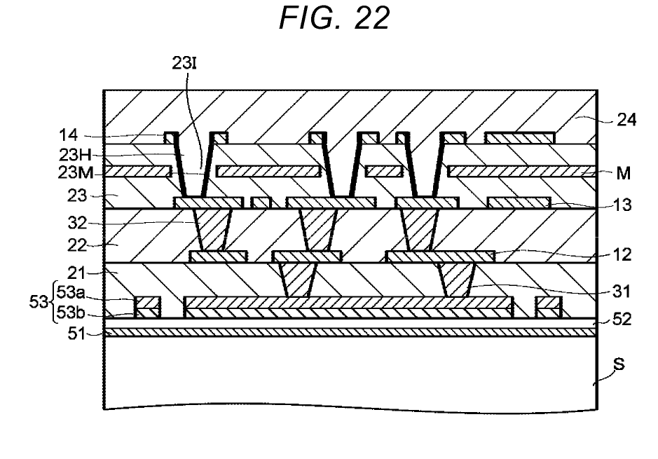

Next, after a coarsening treatment is performed on the fourth conductor layer 14, a resin film (a resin insulating material) is laminated on the third resin insulating layer 23 so as to cover the fourth conductor layer 14 and fill the through holes 23H as shown in FIG. 22, and is cured through pressurization and heating in a vacuum, thereby forming the fourth resin insulating layer 24 and forming the resin insulating layer 23I which fills the through holes 23H.

After that, the same treatments as in the processes shown in FIGS. 15 to 17 of the first embodiment are performed, and the wiring substrate 10A as shown in FIG. 18 is obtained.

In the embodiment, in the processes shown in FIGS. 19 to 22, the through holes 23H are formed in the metal core substrate 10C, the plating layer 23M is formed on the inner walls of the through holes 23H, then, the through holes 23H are filled with the insulating layer 23I using a resin sheet for forming the fourth insulating layer 24. In this case, it is possible to simplify the process of manufacturing the wiring substrate 10A by removing processes such as through hole plating with respect to the core substrate, filling of the through holes through resin filling, and a grinding process of a filling resin which are performed in a core substrate-including wiring substrate of the related art.

In the embodiment, in a method of manufacturing a so-called coreless wiring substrate in which a laminate structure having at least one conductor layer and at least one resin insulating layer laminated on a supporting substrate is formed, the metal core substrate 20C is laminated along with the first laminate structure 20A, and, furthermore, the second laminate structure 20B having the same configuration is laminated on the metal core substrate 20C. In the method of manufacturing a coreless wiring substrate, since the supporting substrate is removed after forming the laminate structure on the supporting substrate in the above manner, ultimately, a configuration in which the metal core substrate is sandwiched by the laminate structures made of at least one conductor layer and at least one resin insulating layer, that is, a wiring substrate having the metal core substrate remains.

In the embodiment, since the method of manufacturing a coreless wiring substrate is used when manufacturing the wiring substrate 10A having the metal core substrate 20C, in the manufacturing processes, the wiring substrate 10A configured of the first laminate structure 20A, the second laminate structure 20B and the metal core substrate 20C is formed on the supporting substrate S. Therefore, even in a case in which the thickness of the metal core substrate 20C is thinned, the thickness of the supporting substrate S is sufficiently thickened so that a decrease in the stiffness of an assembly in a manufacturing process can be prevented.

Therefore, an assembly in a manufacturing process can be horizontally transported, and it is possible to avoid the fact that the assembly comes in contact with a transporting device during transportation such that the assembly is damaged. In addition, when the assembly is fixed and provided for a predetermined manufacturing process, it is also possible to avoid the fact that the assembly is bent, and it becomes difficult to accurately perform, for example, a plating treatment in the respective manufacturing processes. Therefore, it is possible to obtain the wiring substrate 10A having the thin metal core substrate 20C at a high yield, and it becomes possible to thin the wiring substrate 10A having the metal core substrate 20C.

In addition, the metal core substrate 20C in the wiring substrate 10A has the metal plate M having an excellent stiffness. Therefore, even after the wiring substrate 10A is peeled off from the supporting substrate S, an assembly in a manufacturing process can be horizontally transported, and it is possible to avoid the fact that the assembly comes in contact with a transporting device during transportation such that the metal core substrate or the assembly is damaged. In addition, when the assembly is fixed and provided for a predetermined manufacturing process, it is possible to avoid the fact that the assembly is bent, and it becomes difficult to accurately perform, for example, a plating treatment, soldering printing, and the like in the respective manufacturing processes. Therefore, it is possible to obtain the wiring substrate 10A having a thin metal core substrate at a high yield.

The method of the embodiment is not limited to manufacturing of a core substrate-including wiring substrate which has a thin core substrate, including a structure in which the core substrate or an assembly in a manufacturing process would bend in an ordinary manufacturing method so as to decrease the manufacturing yield, that can be applied to a case in which the core substrate is thick, and that can be manufactured using an ordinary manufacturing method at a high yield.

Thus far, the invention has been described in detail using specific examples, but the invention is not limited to the above contents, and any modifications or variations are permitted within the scope of the invention.

In the embodiment, the methods of manufacturing a wiring substrate in which the wiring substrates 10 and 10A are obtained by forming the first resist layer 41 and the second resist layer 42 after removing the supporting substrate S have been described; however, in a case in which it is attempted to make a multilayer, the manufacturing method may have a process of further laminating conductor layer(s) and resin insulating layer(s) on the surfaces of the first laminate structure 20A and the second laminate structure 20B after removing the supporting substrate S.

In the embodiment, the method of manufacturing a wiring substrate in which the conductor layers and the resin insulating layers are sequentially laminated from the side of the conductor layers which function as a rear surface land for connecting to a major board toward the side of the conductor layers which function as a pad (FC pad) for flip chip connection of a semiconductor element and the like has been described, but the laminating order is not particularly limited, and the conductor layers and the resin insulating layers may be laminated from the side of the conductor layers which function as a FC pad toward the side of the conductor layers which function as a rear surface land.

What is claimed is:

1. A method of manufacturing a wiring substrate comprising:
a process of forming a first laminate structure in which one or more conductor layers and one or more resin insulating layers are laminated on a supporting substrate;
a process of forming a metal core substrate, which has a metal layer disposed on a top main surface thereof, on the first laminate structure so that a bottom main surface of the metal core substrate comes in contact with the first laminate structure; and
a process of forming a second laminate structure in which one or more conductor layers and one or more resin insulating layers are laminated on the metal core substrate.

2. The method of manufacturing a wiring substrate according to claim 1, wherein the process of forming the metal core substrate comprises laminating, in the following order:
a first insulating resin layer,
a metal plate in which a plurality of metal plate through holes are formed,
a second insulating resin layer, and
the metal layer.

3. The method of manufacturing a wiring substrate according to claim 2, wherein the process of forming the metal core substrate further comprises:
forming through holes in the metal core substrate at locations of the plurality of metal plate through holes; and
filling the through holes through plating.

4. The method of manufacturing a wiring substrate according to claim 2, wherein the process of forming the metal core substrate further comprises:
forming through holes in the metal core substrate at locations of the plurality of metal plate through holes;
forming a plate layer on inner walls of the through holes formed in the metal core substrate; and
forming a resin insulating layer using a resin insulating material that at least fills the through holes formed in the metal core substrate.

5. The method of manufacturing a wiring substrate according to claim 3, wherein the through holes are formed in the metal core substrate through radiation of laser light.

6. The method of manufacturing a wiring substrate according to claim 4, wherein the through holes are formed in the metal core substrate through radiation of laser light.
